(19) United States
(12) Patent Application Publication
(10) Pub. No.: US 2025/0140437 A1
(43) Pub. Date: May 1, 2025

(54) SILVER PASTE, AND PREPARATION METHOD AND USE THEREOF

(71) Applicants: SOLDERWELL MICROELECTRONIC PACKAGING MATERIALS CO., LTD., Guangzhou (CN); TIANGONG UNIVERSITY, Tianjin (CN)

(72) Inventors: Yunhui Mei, Tianjin (CN); Bowen Zhang, Tianjin (CN); Zhihao Li, Guangzhou (CN); Kun Du, Guangzhou (CN); Xinyan Lu, Tianjin (CN); Shaoqiong Zhang, Tianjin (CN)

(21) Appl. No.: 19/008,698

(22) Filed: Jan. 3, 2025

Related U.S. Application Data
(63) Continuation of application No. PCT/CN2023/108499, filed on Jul. 21, 2023.

(30) Foreign Application Priority Data
Dec. 26, 2022 (CN) 202211670734.1

(51) Int. Cl. H01B 1/22; H01L 23/00

(52) U.S. Cl. CPC H01B 1/22; H01L 24/29; H01L 24/32; H01L 24/83; H01L 2224/29139; H01L 2224/29194; H01L 2224/32225; H01L 2224/83091; H01L 2224/83097; H01L 2224/8384; H01L 2924/37

(57) ABSTRACT

The present disclosure relates to silver paste, and a preparation method and a use thereof, which belong to the field of device packaging technology. The silver paste of the present disclosure is prepared by a silver-ammonia complex and an aldehyde-containing organic solvent, wherein a molar ratio of the silver-ammonia complex to the aldehyde-containing organic solvent is in a range of from 1:1 to 1:5; the silver-ammonia complex is prepared by a silver β-ketocarboxylate and an amino-containing organic solvent; and a molar ratio of the silver β-ketocarboxylate to the amino-containing organic solvent is in a range of from 1:1 to 1:5. The silver paste of the present disclosure can achieve large-area (≥30×30 cm²) packaging and interconnection of a wide-bandgap semiconductor device within 300° C. under a low pressure (≤1 MPa) or without pressures.

### CROSS-REFERENCE TO RELATED APPLICATIONS

The present application is a continuation application of PCT application No. PCT/CN2023/108499 filed on Jul. 21, 2023, which claims the benefit of Chinese Patent Application No. 202211670734.1 filed on Dec. 26, 2022. The contents of all of the aforementioned applications are incorporated by reference herein in their entirety.

### TECHNICAL FIELD

The present disclosure relates to the field of device packaging technology, and particularly it relates to silver paste, and a preparation method and a use thereof.

### BACKGROUND

With increasing improvements of power performance and endurance of electric vehicles, wide bandgap semiconductor devices, as a core of a motor drive and control system, are not only required to adapt to a high-temperature and strong-vibration operating environment of the electric vehicles, but also are required to cope with harsh operating conditions, such as, a large temperature difference and a large current field stress impact, caused by frequent start-stop under complex electrical, thermal and mechanical stress environments, so as to ensure that the electric vehicles have triple attributes, such as strong power, high efficiency and safety and reliability.

In a packaging structure of the wide bandgap semiconductor devices, packaging of interconnection materials not only determines electrical properties of the device, but also relates to heat dissipation characteristics and long-term service reliability of the device, and thus it is critical for the motor drive and control system of electric vehicles to work, with high reliability, long service life and temperature resistance. In consideration of thermal, electrical and mechanical properties of connection interfaces of the wide bandgap semiconductor devices and their packaging processes, low-temperature sinter-joining technology, represented by micro-nano silver paste, has been widely developed.

However, since the wide bandgap semiconductor devices have greater current carrying capacity and lower impedance, they have much higher requirements of heat dissipation than those of traditional silicon devices. Thus existing small-area bonding can no longer satisfy the requirements of heat dissipation of the wide bandgap semiconductor devices, and it is urgent to explore interconnection materials suitable for large-area bonding. Although silver sintering technology has been successfully applied in the field of small-area interconnection, it is usually required to increase driving force of sintering in the process of large-area interconnection through physical methods, such as, by increasing sintering temperatures and sintering pressures. An increase in sintering temperatures and sintering pressures will not only increase difficulty of processes and put higher requirements on equipment, but also will cause damage to chips, reduce product yields and increase costs. Therefore, the key to achieving large-area bonding is to prepare novel silver paste that can be compactly sintered under a low-temperature and low-pressure condition.

### SUMMARY OF THE DISCLOSURE

An objective of the present disclosure is to overcome shortcomings of the prior art and provide silver paste, a preparation method and a use thereof. In the present disclosure, large-area (≥30×30 cm²) packaging and interconnection of a wide-bandgap semiconductor device can be well achieved under a low sintering pressure (0-1 MPa) at a low sintering temperature (200-300° C.)

To achieve the above objective, the present disclosure provides a technical solution as follows.

In a first aspect, the present disclosure provides silver paste, which is prepared by a silver-ammonia complex and an aldehyde-containing organic solvent (R1-CHO, R1 is an alkyl), wherein a molar ratio of the silver-ammonia complex to the aldehyde-containing organic solvent is in a range of from 1:1 to 1:5; the silver-ammonia complex is prepared by a silver β-ketocarboxylate and an amino-containing organic solvent; and a molar ratio of the silver β-ketocarboxylate to the amino-containing organic solvent is in a range of from 1:1 to 1:5.

As a preferred embodiment of the silver paste of the present disclosure, the molar ratio of the silver-ammonia complex to the aldehyde-containing organic solvent is in a range of from 1:2 to 1:4; and the molar ratio of the silver β-ketocarboxylate to the amino-containing organic solvent is in a range of from 1:2 to 1:4.

In the present disclosure, the silver β-ketocarboxylate (C₄H₅O₄Ag) has an aldehyde group (—CHO) and a carboxyl group (—COOH) simultaneously, and forms a silver-ammonia complex ([Ag(R₂NH₂)₂]⁺, R2 is an alkyl) with the amino-containing organic solvent. The silver-ammonia complex has high activity, and it not only can effectively prevent agglomeration of nanoparticles, improve compactness of sintering, but also can reduce a sintering temperature and a sintering pressure of large-area (≥30×30 cm²) packaging and interconnection of a wide-bandgap semiconductor device during the sintering process. Further, the aldehyde-containing organic solvent and the silver-ammonia complex undergo a silver mirror reaction, which is conducive to promoting decomposition of the silver paste. The resulting silver particles can reduce porosity of the silver paste, thereby further improving the sintering compactness. In addition, the aldehyde-containing organic solvent has a strong reducing property and realizes decomposition through self-oxidation. Besides, while inhibiting oxidation of a substrate, the aldehyde-containing organic solvent will not cause sintering residues, which further reduces the sintering temperature and the sintering pressure of large-area (≥30×30 cm²) packaging and interconnection of the wide-bandgap semiconductor device.

In the present disclosure, the molar ratio of the silver β-ketocarboxylate to the amino-containing organic solvent and the molar ratio of the silver-ammonia complex to the aldehyde-containing organic solvent will both affect performance of silver paste. When the molar ratio of the silver β-ketocarboxylate to the amino-containing organic solvent is 1:2, the silver β-ketocarboxylate and amino will form a saturated silver-ammonia complex, which has high activity and is easier to sinter and decompose. If the molar ratio of the silver β-ketocarboxylate to the amino-containing organic solvent is too small, the saturated silver-ammonia complex cannot be formed; if the molar ratio of the silver β-ketocarboxylate to the amino-containing organic solvent is too large, an excessive amino-containing solvent will be introduced, which will cause organic residues during sintering. In addition, if the molar ratio of the silver-ammonia complex to the aldehyde-containing organic solvent is excessively small, the silver paste has a low driving force of sintering and thus cannot be thoroughly decomposed; if the molar ratio of the silver-ammonia complex to the aldehyde-containing organic solvent is excessively large, an excessive organic solvent is introduced and the silver paste has an excessively low solid content, which is not conducive to coating and forming an interconnection structure. The inventors have found that the molar ratio of the silver β-ketocarboxylate to the amino-containing organic solvent is preferably 1:2, and the molar ratio of the silver-ammonia complex to the aldehyde-containing organic solvent is preferably 1:1.

As a preferred embodiment of the silver paste of the present disclosure, the aldehyde-containing organic solvent is a fatty aldehyde containing less than 12 carbon atoms.

Preferably, the aldehyde-containing organic solvent is at least one of acetaldehyde, propionaldehyde and butyraldehyde.

Selection of the above-mentioned aldehyde-containing organic solvent is more conducive to improving the performance of the silver paste and the bonding strength of the semiconductor device.

As a preferred embodiment of the silver paste of the present disclosure, the amino-containing organic solvent contains no more than 10 carbon atoms.

Preferably, the amino-containing organic solvent is at least one of 2-amino-2-methyl-1-propanol, 2-isopropylamine, ethanolamine and hexylamine. The above-mentioned amino-containing organic solvent can obtain a silver ammonia complex with more stable performance, which is conducive to improving compactness of the packaging and interconnection structure of the wide-bandgap semiconductor device.

In a second aspect, the present disclosure provides a method for preparing the above-mentioned silver paste, comprising the following steps:
S1: mixing the silver β-ketocarboxylate and the amino-containing organic solvent evenly to obtain a silver-ammonia complex;
S2: mixing the silver-ammonia complex obtained in Step S1 with an aldehyde-containing organic solvent evenly to obtain the silver paste.

In a third aspect, the present disclosure provides a use of the above-mentioned silver paste in a packaging and interconnection structure of a wide-bandgap semiconductor device.

Preferably, the packaging and interconnection structure of the wide-bandgap semiconductor device comprises an upper substrate, a lower substrate and a connection layer for connecting the upper substrate and the lower substrate, wherein the connection layer is formed by sintering the above-mentioned silver paste through a sintering process.

Preferably, a sintering temperature is in a range of from 200° C. to 300° C., a sintering time is in a range of from 10 min to 30 min, and a sintering pressure is in a range of from 0 to 1 MPa.

Preferably, the upper substrate or the lower substrate comprises a copper, gold or silver sheet; a ceramic or silicon sheet coated with copper, gold or silver on a surface layer; and a functional device.

Compared with the prior art, the present disclosure brings the following beneficial effects. The silver paste of the present disclosure can achieve large-area (≥30×30 cm²) packaging and interconnection of a wide-bandgap semiconductor device within 300° C. under a low pressure (≤1 MPa) or without pressures. Besides, a connection layer formed by sintering the silver paste has a well-bonded, uniform and compacted connection interface, and has shear strength of up to 35 MPa. Therefore, the silver paste can be well applied to large-area packaging and interconnection of electronic devices.

### BRIEF DESCRIPTION OF DRAWINGS

FIG. 1 is a flow chart for preparing silver paste of the present disclosure;

FIG. 2 is a scanning electron microscope image showing a cross section of the sintered silver paste of the present disclosure;

FIG. 3 is a flow chart for applying the silver paste of the present disclosure.

### DETAILED DESCRIPTION

In order to better illustrate the objective, technical solutions and advantages of the present disclosure, the present disclosure will be further described in conjunction with specific embodiments and comparative examples. It is noted that the specific embodiments are intended to understand contents of the present disclosure in detail, rather than to limit the present disclosure. All other embodiments obtained by those skilled in the art, without any creative work, shall fall into scopes of protection of the present disclosure. Unless otherwise specified, experimental reagents and instruments involved in the examples of the present disclosure are ordinary reagents and instruments commonly used.

Raw materials used in the examples and in comparative examples are now described as follows.

Silver β-ketocarboxylate: its chemical name is silver β-methyl acetoacetate, and its chemical formula is C₄H₅O₄Ag; the silver β-methyl acetoacetate in the present disclosure is prepared according to a published reference, DOI: 10.1039/C5DT00773A.

### Example 1

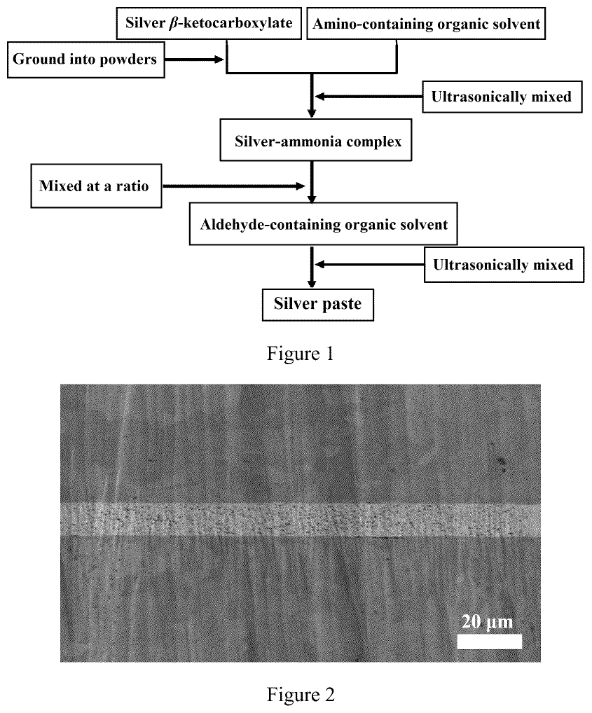

Preparation of silver paste: As shown in FIG. 1, silver β-ketocarboxylate and ethanolamine were evenly mixed at a molar ratio of 1:1 at room temperature to obtain an unsaturated silver-ammonia complex; then the unsaturated silver-ammonia complex and acetaldehyde were mixed at a molar ratio of 1:1, and ultrasonically mixed in an ultrasonic machine for 30 min to obtain silver paste.

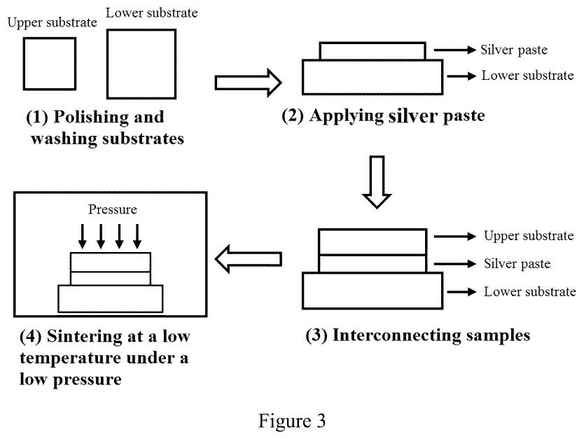

The silver paste prepared above was applied to a packaging and interconnection structure of an electronic device. The packaging and interconnection structure included an upper substrate and a lower substrate, both of which were pure copper substrates, wherein the area of the upper substrate was 30×30 cm², and the area of the lower substrate was 35×35 cm². As shown in FIG. 3, specific steps for applying the prepared silver paste were as follows:
S1: Treatment of substrates: The pure copper substrates (i.e., the upper substrate and the lower substrate) were polished with sandpaper to remove a copper oxide layer on surfaces of the pure copper substrates, then the polished pure copper substrates were ultrasonically washed in anhydrous ethanol for 2 min to remove impurities on their surfaces, then placed in a vacuum drying oven and dried at 60° C. for 3 min to remove the anhydrous ethanol.
S2: The silver paste prepared in Example 1 was uniformly coated on a connection surface of the lower substrate obtained in Step S1 by screen printing, with a coating thickness of 8 μm. Then a connection surface of the upper substrate obtained in Step S1 was attached to the silver paste on the lower substrate to form a stacking structure of the upper substrate/the silver paste/the lower substrate.
S3: The stacking structure of the upper substrate/the silver paste/the lower substrate obtained in Step S2 was placed in a pressure-assisted sintering furnace, heated to 250° C. at a heating rate of 10° C./min, and held at 250° C. without pressure for 30 min, so that a silver paste coating was sintered to form a connection layer, and then naturally cooled to obtain a packaging and interconnection structure. After sintering, a cross section of the sintered silver paste was shown in FIG. 2.

The interconnection structure was divided into small pieces with a dimension of 5×5 cm². The lower substrate of the interconnection structure was fixed, and the upper substrate was pushed by a pusher. It was found that a force required for destroying the interconnection structure was about 500 N, which was then divided by the connecting area to obtain shear strength of the connection layer, formed by sintering the silver paste prepared in Example 1 after cooling. The shear strength of the connection layer was 20±2 MPa.

### Example 2

Preparation of silver paste: Silver β-ketocarboxylate and hexylamine were evenly mixed at a molar ratio of 1:3 at room temperature to obtain a saturated silver-ammonia complex; then the saturated silver-ammonia complex and acetaldehyde were mixed at a molar ratio of 1:1, and ultrasonically mixed in an ultrasonic machine for 30 min to obtain silver paste.

The silver paste prepared above was applied to a packaging and interconnection structure of an electronic device. The packaging and interconnection structure included an upper substrate and a lower substrate, both of which were pure copper substrates, wherein the area of the upper substrate was 30×30 cm², and the area of the lower substrate was 35×35 cm². Specific steps were as follows:
S1: Treatment of substrates: The pure copper substrates (i.e., the upper substrate and the lower substrate) were polished with sandpaper to remove a copper oxide layer on surfaces of the pure copper substrates, then the polished pure copper substrates were ultrasonically washed in anhydrous ethanol for 2 min to remove impurities on their surfaces, then placed in a vacuum drying oven and dried at 60° C. for 3 min to remove the anhydrous ethanol.
S2: The silver paste prepared in Example 1 was uniformly coated on a connection surface of the lower substrate obtained in Step S1 by screen printing, with a coating thickness of 10 μm. Then a connection surface of the upper substrate obtained in Step S1 was attached to the silver paste on the lower substrate to form a stacking structure of the upper substrate/the silver paste/the lower substrate.
S3: The stacking structure of the upper substrate/the silver paste/the lower substrate obtained in Step S2 was placed in a pressure-assisted sintering furnace, heated to 280° C. at a heating rate of 10° C./min, and held at 280° C. under a pressure of 0.5 MPa for 30 min, so that a silver paste coating was sintered to form a connection layer, and then naturally cooled to obtain a packaging and interconnection structure.

The interconnection structure was divided into small pieces with a dimension of 5×5 cm². The lower substrate of the interconnection structure was fixed, and the upper substrate was pushed by a pusher. It was found that a force required for destroying the interconnection structure was about 620 N, which was then divided by the connecting area to obtain shear strength of the connection layer, formed by sintering the silver paste prepared in Example 2 after cooling. The shear strength of the connection layer was 25±2 MPa.

### Example 3

Preparation of silver paste: Silver-ketocarboxylate and 2-amino-2-methyl-1-propanol were evenly mixed at a molar ratio of 1:3 at room temperature to obtain a saturated silver-ammonia complex; then the saturated silver-ammonia complex and acetaldehyde were mixed at a molar ratio of 1:3, and ultrasonically mixed in an ultrasonic machine for 30 min to obtain silver paste.

The silver paste prepared above was applied to a packaging and interconnection structure of an electronic device. The packaging and interconnection structure included an upper substrate and a lower substrate, both of which were pure copper substrates, wherein the area of the upper substrate was 30×30 cm², and the area of the lower substrate was 35×35 cm². Specific steps were as follows:
S1: Treatment of substrates: The pure copper substrates (i.e., the upper substrate and the lower substrate) were polished with sandpaper to remove a copper oxide layer on surfaces of the pure copper substrates, then the polished pure copper substrates were ultrasonically washed in anhydrous ethanol for 2 min to remove impurities on their surfaces, then placed in a vacuum drying oven and dried at 60° C. for 3 min to remove the anhydrous ethanol.
S2: The silver paste prepared in Example 1 was uniformly coated on a connection surface of the lower substrate obtained in Step S1 by screen printing, with a coating thickness of 8 μm. Then a connection surface of the upper substrate obtained in Step S1 was attached to the silver paste on the lower substrate to form a stacking structure of the upper substrate/the silver paste/the lower substrate.
S3: The stacking structure of the upper substrate/the silver paste/the lower substrate obtained in Step S2 was placed in a pressure-assisted sintering furnace, heated to 300° C. at a heating rate of 10° C./min, and held at 300° C. under a pressure of 0.8 MPa for 30 min, so that a silver paste coating was sintered to form a connection layer, and then naturally cooled to obtain a packaging and interconnection structure.

The interconnection structure was divided into small pieces with a dimension of 5×5 cm². The lower substrate of the interconnection structure was fixed, and the upper substrate was pushed by a pusher. It was found that a force required for destroying the interconnection structure was about 740 N, which was then divided by the connecting area to obtain shear strength of the connection layer, formed by sintering the silver paste prepared in Example 3 after cooling. The shear strength of the connection layer was 30±2 MPa.

### Example 4

Preparation of silver paste: Silver β-ketocarboxylate and 2-amino-2-methyl-1-propanol were evenly mixed at a molar ratio of 1:5 at room temperature to obtain a saturated silver-ammonia complex; then the saturated silver-ammonia complex and acetaldehyde were mixed at a molar ratio of 1:5, and ultrasonically mixed in an ultrasonic machine for 30 min to obtain silver paste.

The silver paste prepared above was applied to a packaging and interconnection structure of an electronic device. The packaging and interconnection structure included an upper substrate and a lower substrate, both of which were pure copper substrates, wherein the area of the upper substrate was 30×30 cm², and the area of the lower substrate was 35×35 cm². Specific steps were as follows:
S1: Treatment of substrates: The pure copper substrates (i.e., the upper substrate and the lower substrate) were polished with sandpaper to remove a copper oxide layer on surfaces of the pure copper substrates, then the polished pure copper substrates were ultrasonically washed in anhydrous ethanol for 2 min to remove impurities on their surfaces, then placed in a vacuum drying oven and dried at 60° C. for 3 min to remove the anhydrous ethanol.
S2: The silver paste prepared in Example 1 was uniformly coated on a connection surface of the lower substrate obtained in Step S1 by screen printing, with a coating thickness of 8 μm. Then a connection surface of the upper substrate obtained in Step S1 was attached to the silver paste on the lower substrate to form a stacking structure of the upper substrate/the silver paste/the lower substrate.
S3: The stacking structure of the upper substrate/the silver paste/the lower substrate obtained in Step S2 was placed in a pressure-assisted sintering furnace, heated to 300° C. at a heating rate of 10° C./min, and held at 300° C. under a pressure of 1 MPa for 30 min, so that a silver paste coating was sintered to form a connection layer, and then naturally cooled to obtain a packaging and interconnection structure.

After testing, shear strength of the connection layer, formed by sintering the silver paste prepared in Example 4 after cooling, was tested to be 25±2 MPa.

### Comparative Example 1

Silver paste, and a preparation method and a use thereof were provided in Comparative Example 1. The difference between Comparative Example 1 and Example 1 was that the molar ratio of silver β-ketocarboxylate to ethanolamine was 1:0.5.

Shear strength of the connection layer obtained in Comparative Example 1 was tested according to the test method disclosed in Example 1, and it was 3 MPa.

### Comparative Example 2

Silver paste, and a preparation method and a use thereof were provided in Comparative Example 2. The difference between Comparative Example 2 and Example 1 was that the molar ratio of silver β-ketocarboxylate to ethanolamine was 1:5.5.

A solid content of the obtained silver paste was excessively low, so that an effective connection cannot be formed by coating.

### Comparative Example 3

Silver paste, and a preparation method and a use thereof were provided in Comparative Example 3. The difference between Comparative Example 3 and Example 1 was that the molar ratio of the unsaturated silver-ammonia complex to the acetaldehyde was 1:0.5.

Shear strength of the connection layer obtained in Comparative Example 3 was tested according to the test method disclosed in Example 1, and it was 5 MPa.

### Comparative Example 4

Silver paste, and a preparation method and a use thereof were provided in Comparative Example 4. The difference between Comparative Example 4 and Example 1 was that the molar ratio of the unsaturated silver-ammonia complex to the acetaldehyde was 1:5.5.

A solid content of the obtained silver paste was excessively low, so that an effective connection cannot be formed by coating.

### Comparative Example 5

Silver paste, and a preparation method and a use thereof were provided in Comparative Example 5. The difference between Comparative Example 5 and Example 1 was that ethanol was adopted to replace acetaldehyde, and the molar ratio of the unsaturated silver-ammonia complex to ethanol was 1:1.

Silver nanoparticles cannot be synthesized by reactions, so that an effective connection cannot be formed by sintering.

Finally, it should be noted that the above embodiments are only intended to illustrate the technical solutions of the present disclosure, rather than to limit the scope of protection of the present disclosure. Although the present disclosure has been described in detail with reference to preferred embodiments, those skilled in the art should understand that the technical solutions of the present disclosure can be modified or equivalently replaced, without departing from the essence and scope of the technical solution of the present disclosure.

1. Silver paste, prepared from a silver-ammonia complex and an aldehyde-containing organic solvent, wherein a molar ratio of the silver-ammonia complex to the aldehyde-containing organic solvent is in a range of from 1:1 to 1:5; the silver-ammonia complex is prepared by a silver β-ketocarboxylate and an amino-containing organic solvent; and a molar ratio of the silver β-ketocarboxylate to the amino-containing organic solvent is in a range of from 1:1 to 1:5.

2. The silver paste according to claim 1, wherein the molar ratio of the silver-ammonia complex to the aldehyde-containing organic solvent is in a range of from 1:2 to 1:4; and the molar ratio of the silver-ketocarboxylate to the amino-containing organic solvent is in a range of from 1:2 to 1:4.

3. The silver paste according to claim 1, wherein the aldehyde-containing organic solvent is a fatty aldehyde containing less than 12 carbon atoms.

4. The silver paste according to claim 1, wherein the amino-containing organic solvent contains no more than 10 carbon atoms.

5. A method for preparing the silver paste according to claim 1, comprising following steps:
S1: mixing the silver β-ketocarboxylate and the amino-containing organic solvent evenly to obtain the silver-ammonia complex;
S2: mixing the silver-ammonia complex obtained in Step S1 with the aldehyde-containing organic solvent evenly to obtain the silver paste.

6. The method according to claim 5, wherein the molar ratio of the silver-ammonia complex to the aldehyde-containing organic solvent is in a range of from 1:2 to 1:4; and the molar ratio of the silver β-ketocarboxylate to the amino-containing organic solvent is in a range of from 1:2 to 1:4.

7. The method according to claim 5, wherein the aldehyde-containing organic solvent is a fatty aldehyde containing less than 12 carbon atoms.

8. The method according to claim 5, wherein the amino-containing organic solvent contains no more than 10 carbon atoms.

9. A method of preparing a packaging and interconnection structure of a wide-bandgap semiconductor device, comprising a step of
applying the silver paste according to claim 1 for connecting elements, and sintering the silver paste.

10. The method according to claim 9, wherein the packaging and interconnection structure of the wide-bandgap semiconductor device comprises an upper substrate, a lower substrate and a connection layer for connecting the upper substrate and the lower substrate, wherein the connection layer is formed by sintering the silver paste through a sintering process.

11. The method according to claim 10, wherein the molar ratio of the silver-ammonia complex to the aldehyde-containing organic solvent is in a range of from 1:2 to 1:4; and the molar ratio of the silver β-ketocarboxylate to the amino-containing organic solvent is in a range of from 1:2 to 1:4.

12. The method according to claim 10, wherein the aldehyde-containing organic solvent is a fatty aldehyde containing less than 12 carbon atoms.

13. The method according to claim 10, wherein the amino-containing organic solvent contains no more than 10 carbon atoms.

14. The method according to claim 10, wherein a sintering temperature is in a range of from 200° C. to 300° C., a sintering time is in a range of from 10 min to 30 min, and a sintering pressure is in a range of from 0 to 1 MPa.
